(19) United States
(12) Patent Application Publication
(10) Pub. No.: US 2010/0263838 A1
(43) Pub. Date: Oct. 21, 2010

(54) Synthetic Jet Ejector for Augmentation of Pumped Liquid Loop Cooling and Enhancement of Pool and Flow Boiling

(75) Inventors: Raghavendran Mahalingam, Austin, TX (US); Samuel Neil Heffington, Austin, TX (US); Ari Glezer, Atlanta, GA (US)

Correspondence Address: FORTKORT & HOUSTON P.C., 9442 N. CAPITAL OF TEXAS HIGHWAY, ARBORETUM PLAZA ONE, SUITE 500, AUSTIN, TX, 78759, US

(73) Assignee: Nuventix Inc.

(21) Appl. No.: 12/829,808

(22) Filed: Jul. 2, 2010

Related U.S. Application Data
(63) Continuation of application No. 11/494,913, filed on Jul. 28, 2006.
(60) Provisional application No. 60/704,049, filed on Jul. 29, 2005.

(51) Int. Cl. H01L 23/473; F28D 15/00

(52) U.S. Cl. 165/104.31

(57) ABSTRACT

A thermal management system (201) is disclosed which comprises (a) a liquid medium (207), (b) a heat generating device (203) disposed in said medium, (c) a heat transfer device (205) in thermal contact with said heat generating device, said heat transfer device comprising a thermally conductive material and having a channel (213) defined on a surface thereof, and (d) a synthetic jet ejector (223) adapted to direct a jet of the liquid medium along said channel.

### CROSS REFERENCE TO RELATED APPLICATION

This application is a continuation application and claims the benefit of priority from U.S. patent application Ser. No. 11/494,913, now pending, having the same title, and having the same inventors, and which is incorporated herein by reference in its entirety; which application claims the benefit of priority from U.S. Provisional Application No. 60/704,049, filed Jul. 29, 2005, having the same title, and having the same inventors, and which is incorporated herein by reference in its entirety.

### FIELD OF THE DISCLOSURE

The present disclosure relates generally to synthetic jet ejectors, and more specifically to the use of synthetic jet ejectors to augment the flow of liquid in a pumped liquid loop cooling system.

### BACKGROUND OF THE DISCLOSURE

As the size of semiconductor devices has continued to shrink and circuit densities have increased accordingly, thermal management of these devices has become more challenging. This problem is expected to worsen in the foreseeable future. Thus, within the next decade, spatially averaged heat fluxes in microprocessor devices are projected to increase by a factor of two, to well over 100 W/cm², with core regions of these devices experiencing local heat fluxes that are several times higher.

In the past, thermal management in semiconductor devices was often addressed through the use of forced convective air cooling, either alone or in conjunction with various heat sink devices, and was accomplished through the use of fans. However, fan-based cooling systems were found to be undesirable due to the electromagnetic interference and noise attendant to their use. Moreover, the use of fans also requires relatively large moving parts, and corresponding high power inputs, in order to achieve the desired level of heat transfer.

More recently, thermal management systems have been developed which utilize synthetic jet ejectors. These systems are more energy efficient than comparable fan-based systems, and also offer reduced levels of noise and electromagnetic interference. One such system is depicted in FIG. 1. Systems of this type are described in greater detail in U.S. Pat. No. 6,588,497 (Glezer et al.).

The system shown in FIG. 1 utilizes an air-cooled heat transfer module 101 which is based on a ducted heat ejector (DHE) concept. The module utilizes a thermally conductive, high aspect ratio duct 103 that is thermally coupled to one or more IC packages 105. Heat is removed from the IC packages 105 by thermal conduction into the duct shell 107, where it is subsequently transferred to the air moving through the duct. The air flow within the duct 103 is induced through internal forced convection by a pair of low form factor synthetic jet ejectors 109 which are integrated into the duct shell 107. In addition to inducing air flow, the turbulent jet produced by the synthetic jet ejector 109 enables highly-efficient convective heat transfer and heat transport at low volume flow rates through small-scale motions near the heated surfaces, while also inducing vigorous mixing of the core flow within the duct.

While the system disclosed in Glezer et al. represents a very notable improvement in the art of thermal management systems, in light of the aforementioned challenges in the art, a need exists for thermal management systems with even greater heat transfer efficiencies, and which can handle even greater heat flux loads. There is also a need in the art for such a system that is scalable and compact, and that does not contribute significantly to the overall size of the device. These and other needs are met by the devices and methodologies described herein.

### BRIEF DESCRIPTION OF THE DRAWINGS

FIG. 1 is an illustration of a prior art thermal management system based on the use of synthetic jet ejectors;

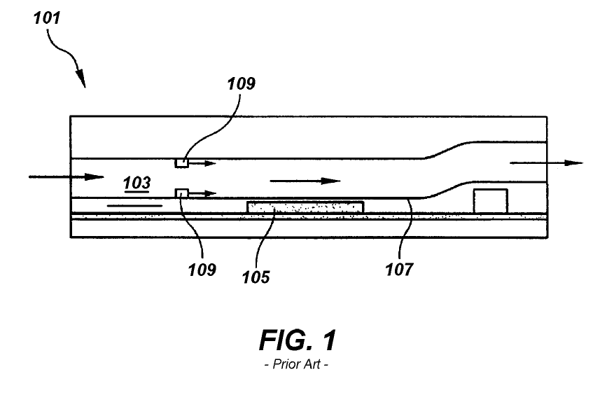

FIG. 2 is an illustration of a first embodiment of a liquid loop cooling system made in accordance with the teachings herein;

FIG. 3 is an illustration of a synthetic jet ejector suitable for use in the thermal management systems described herein;

FIG. 4 is an illustration of a synthetic jet ejector suitable for use in the thermal management systems described herein;

FIG. 5 is an illustration of a synthetic jet ejector suitable for use in the thermal management systems described herein;

FIG. 6 is an illustration of a second embodiment of a liquid loop cooling system made in accordance with the teachings herein; and

FIG. 7 is a perspective view of a first embodiment of the heat exchanger of the liquid loop cooling system of FIG. 6; and

FIG. 8 is a top view of a second embodiment of a heat exchanger suitable for use in the liquid loop cooling system of FIG. 6, and with synthetic jet actuators mounted in the channel of the heat exchanger.

### SUMMARY OF THE DISCLOSURE

In one aspect, a thermal management system is provided which comprises (a) a liquid medium, (b) a heat generating device disposed in said medium, (c) a heat exchanger in thermal contact with said heat generating element, said heat exchanger comprising a thermally conductive material and having a channel defined on a surface thereof, and (d) an actuator adapted to direct a jet of the liquid medium along said channel.

In another aspect, a method for dissipating heat from a heat generating device is provided. In accordance with the method, a heat generating device is provided which is to be cooled, the heat generating device being in thermal contact with a heat exchanger which is immersed in a liquid medium and which has a channel defined in a surface thereof. A synthetic jet ejector is also provided which is positioned to direct a jet of the liquid into said channel, and the synthetic jet ejector is activated.

These and other aspects of the present disclosure are described in greater detail below.

### DETAILED DESCRIPTION

It has now been found that the aforementioned needs can be addressed through the provision of a pumped liquid loop cooling system which utilizes one or more synthetic jet ejectors, in combination with vibration induced boiling enhancement (VIBE), to cool semiconductor die and other heat generating devices by augmenting the flow of liquid coolant through the system. In such a system, the heat generating device may be thermally coupled with a heat exchanger which comprises a plurality of channels, and each of the synthetic jet ejectors may be positioned to direct a jet of the liquid coolant along one of the channels. When energized, each of the synthetic jet ejectors provides one or more high momentum synthetic jets directed in the same direction as the pumped coolant flow, and along the longitudinal axis of one of the channels.

The use of focused jets in liquid loop cooling systems is found to have several advantages. First of all, while the pumps utilized in these systems can provide a suitable global flow of the liquid coolant through the system, the flow rate of the liquid coolant within the channels of the heat exchanger is typically much slower, due to the pressure drop created by the channel walls. This problem worsens as the system becomes smaller. Indeed, such a pressure drop is one of the biggest obstacles to the miniaturization of pumped liquid loop cooling systems. The use of focused jets to direct a stream of liquid into the channels overcomes this problem by reducing this pressure drop, and hence facilitates increased entrainment of the flow of the liquid coolant into the channels.

The use of focused jets in the thermal management systems described herein also significantly improves the efficiency of the heat transfer process. Under conditions in which the liquid coolant is in a non-boiling state, the flow augmentation provided by the use of synthetic jet ejectors increases the rate of local heat transfer in the channel structure, thus resulting in higher heat removal. Under conditions in which the coolant is in a boiling state, these jets induce the rapid ejection of vapor bubbles formed during the boiling process. This dissipates the insulating vapor layer that would otherwise form, and hence delays the onset of critical heat flux. In some applications, as explained in greater detail below, the synthetic jets may also be utilized to create beneficial nucleation sites to enhance the boiling process.

The systems and methodologies described herein further increase the efficiency of the heat transfer process by permitting this process to be augmented locally in accordance with localized thermal loads. For example, the current trend in the semiconductor industry is toward semiconductor devices that generate heat in an increasingly non-uniform manner. This results in the creation of hotspots in these devices which, in many cases, is the first point of thermal failure of the device. Through the provision of directed, localized synthetic jets, these hot spots can be effectively eliminated, thereby reducing the global power requirements of the thermal management system. The reduction in power requirement attendant to the flow augmentation provided by the synthetic jet ejectors also reduces the noise of the system, and improves the reliability of the main pump (or pumps) used to circulate the liquid coolant.

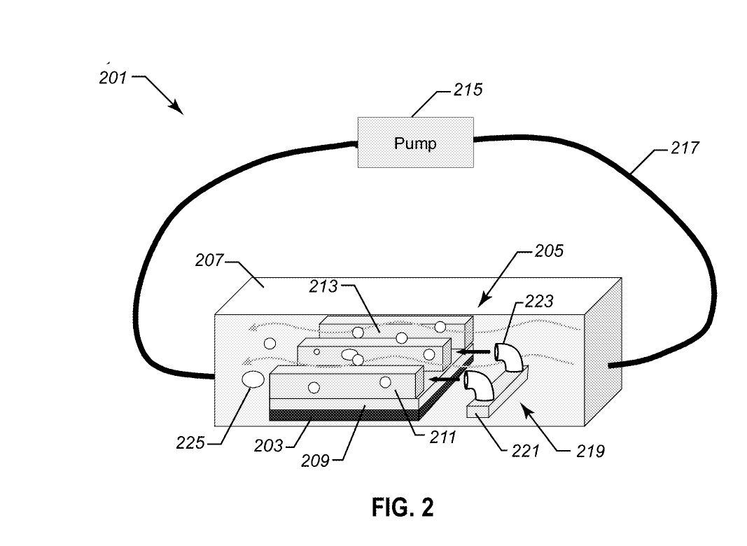

The principles described herein can be further understood with reference to FIG. 2, which illustrates a first, non-limiting embodiment of a liquid loop cooling system 201 made in accordance with the teachings herein. The system 201 comprises a heat generating device 203 which, in this particular embodiment, is a die, and which is in thermal contact with a heat exchanger 205. The heat generating device 203 and the heat exchanger 205 are disposed in a liquid coolant 207. The heat exchanger 205 comprises a planar, thermally conductive plate 209 with a series of ridges 211 disposed thereon that define a plurality of channels 213. A pump 215 and a conduit 217 are provided that operate to maintain a flow of the liquid coolant in a direction generally parallel to the longitudinal axes of the channels 213.

Referring again to FIG. 2, a synthetic jet ejector (SJE) apparatus 219 is provided adjacent to the heat exchanger 205. The synthetic jet ejector 219 comprises a base plate 221 which is equipped with a plurality of nozzles 223. The nozzles 223 are each adapted to produce synthetic jets, and are positioned so that the synthetic jet produced is directed along the longitudinal axis of the channel 213. The nozzles 223 operate to create air bubbles 225 in the fluid flow, which augments the cooling of the heat generating device 203.

While the cooling of a semiconductor die has been specifically illustrated herein, one skilled in the art will appreciate that the devices and methodologies described herein may be applied to the thermal management of a wide variety of heat generating devices. These include, without limitation, printed circuit boards and the components thereof, memory devices, processors, and the like.

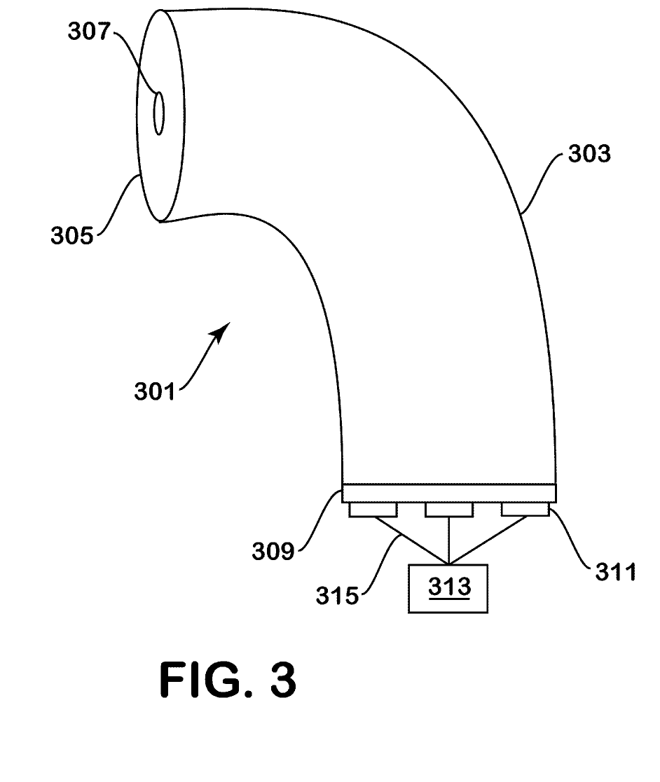

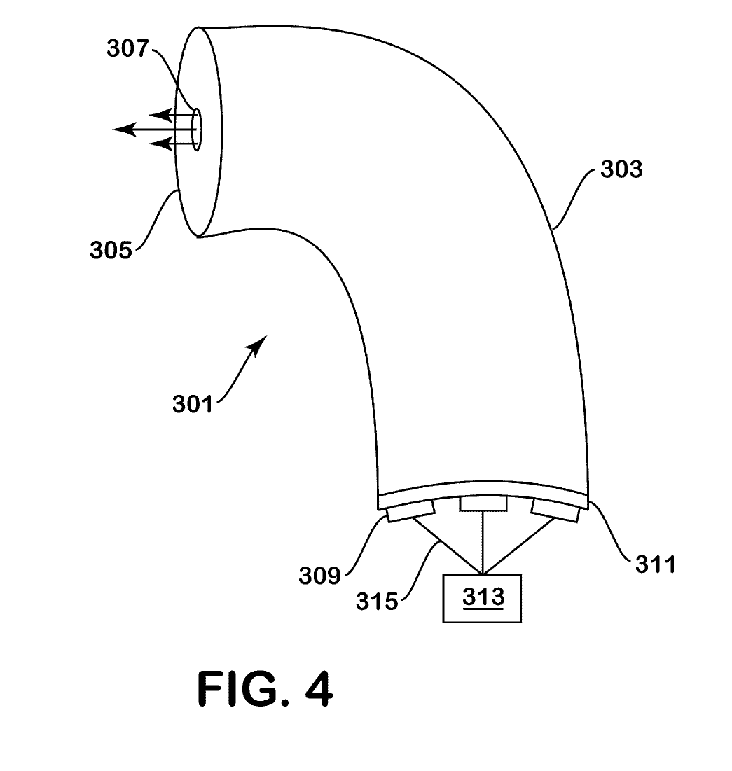

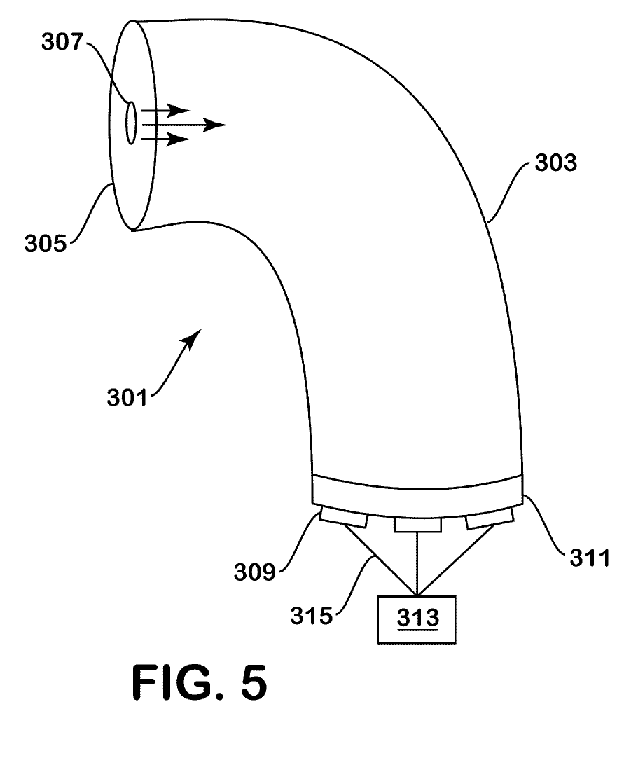

FIGS. 3-5 illustrate one possible, non-limiting embodiment of a synthetic jet ejector 301 suitable for use in the devices and methodologies disclosed herein. The synthetic jet ejector 301 illustrated therein comprises a body 303 that terminates on one end in a wall 305 having an orifice 307 defined therein, and which terminates on the other end in a diaphragm 309. In the particular embodiment depicted, the diaphragm 309 is equipped with a plurality of piezoelectric actuators 311. The actuators 311 are in electrical communication with a driver 313 by way of suitable connectors 315. The driver 313, which may be a wave generator, microcomputer, or other controllable voltage source, operates to create oscillations of a suitable frequency in the diaphragm 309 by causing the actuators 311 to vibrate. During the inward phase of the oscillation, as shown in FIG. 4, a synthetic jet of the liquid coolant is emitted from the orifice 307. During the outward phase of the oscillation, as shown in FIG. 5, the flow is reversed, and liquid coolant is drawn into the synthetic jet ejector 301 through the orifice 307.

It will be appreciated that the shape of the synthetic jet ejector 301, as well as its overall dimensions and the relative size of its components, can vary considerably. For example, any of the various synthetic jet ejector designs disclosed in U.S. Pat. No. 6,588,497 (Glezer et al.), which is incorporated herein by reference, may be incorporated into the thermal management systems described herein.

Moreover, the actuators in these devices may be adapted to operate at ultrasonic or non-ultrasonic frequencies. In some applications, the use of actuators operating at non-ultrasonic frequencies may be preferred, due to the additional nucleation sites, in the form of vapor bubbles, which may be generated at such frequencies. The formation of these vapor bubbles is induced by local accelerations of the liquid coolant in the vicinity of the transducer. These accelerations result in extremely high local velocities in the coolant, and a corresponding reduction in pressure. When the reduction in pressure is sufficiently high, the coolant undergoes localized phase changes at ambient temperatures, thus resulting in cavitation of the coolant. As the transducer oscillates, the cavitation bubbles alternately form and collapse, thereby entraining the surrounding fluid and generating a synthetic jet. As depicted in FIG. 2, some of these tiny cavitation bubbles become entrained in the jet and are directed toward the hot surfaces of the heat exchanger, where they provide excellent nucleation sites for the boiling process.

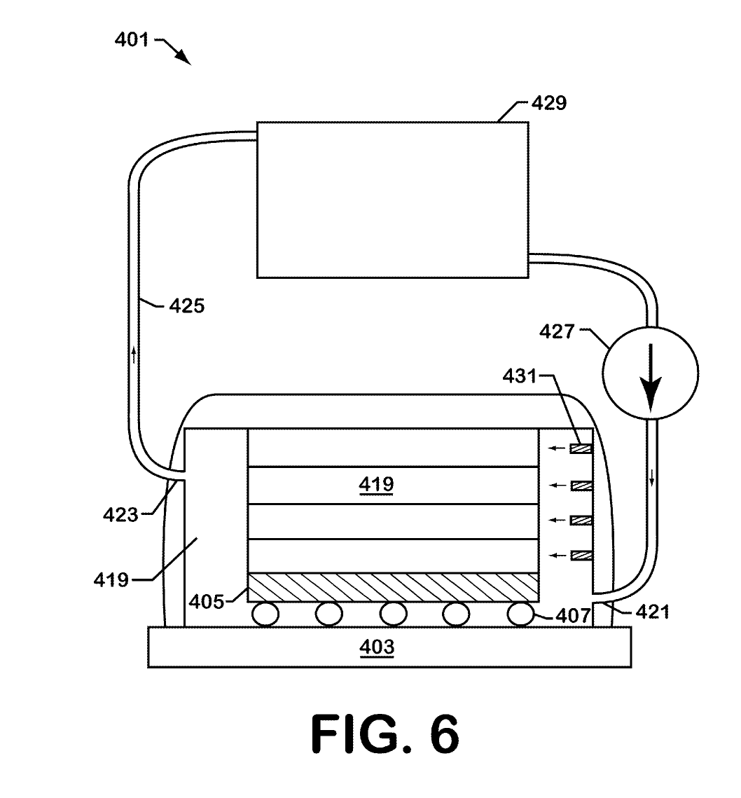

FIG. 6 illustrates a second particular, non-limiting embodiment of a liquid loop cooling system made in accordance with the teachings herein. In the system 401 depicted therein, a printed circuit board 403 is provided which is flip-chip bonded to a die 405 by way of a plurality of solder joints 407. The die 405 has a heat exchanger 409 mounted on a surface thereof.

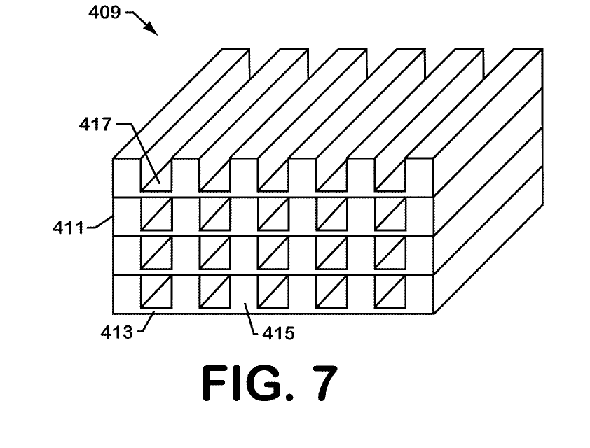

The details of the heat exchanger 409 may be appreciated with reference to FIG. 7. As seen therein, the heat exchanger 409 comprises a stack of individual heat exchanger elements 411. Each of these heat exchanger elements 411 comprises a base portion 413 with a series of parallel ridges 415 thereon that define a plurality of microchannels 417.

Referring again to FIG. 6, the die 405 and the heat exchanger 409 are encapsulated within a chamber 419 having an inlet 421 and an outlet 423. The inlet 421 and outlet 423 are in fluidic communication with a cooling loop 425 through which a cooling liquid flows under the control of an in-line pump 427. A heat sink 429, which acts as a heat exchanger between the liquid coolant and the ambient atmosphere, is also incorporated into the cooling loop 425.

In use, cooled liquid coolant flows into the chamber 419 by way of inlet 421. After entering the chamber 419, the coolant flows through the microchannels 417 (see FIG. 7) of the heat exchanger 409. In so doing, the liquid coolant withdraws heat from the surfaces of the microchannels 417, thereby cooling the die 405. The warmed coolant then exits the chamber 419 through the outlet 423, where it traverses the cooling loop 425 to the heat sink 429. The heat sink 429, which may be fashioned as a liquid-to-air heat exchanger, operates to withdraw heat from the liquid coolant and reject it to the ambient atmosphere. The cooled liquid coolant then exits the heat sink 429 and is routed back to the chamber 419 by the pump 427.

As seen in FIG. 6, the flow of the liquid coolant through the microchannels 417 (see FIG. 7) of the heat exchanger 409 is augmented by a series of synthetic jet actuators 431 that are mounted on an interior wall of the chamber 419 adjacent to the openings of the microchannels 417. As in the previous embodiment described herein, the synthetic jet actuators 431 operate to direct a jet of the liquid coolant along the longitudinal axis of the microchannels 417. The jets so produced have the effect of reducing or eliminating the pressure drop in the microchannels 417, with all of the attendant advantages as have been previously discussed.

The use of a stacked heat exchanger 409 of the type shown in FIG. 7 is particularly advantageous in the cooling system 401 of FIG. 6 in that this type of heat exchanger has the capability to handle on-chip non-uniformities in power. The manifolding and three-dimensional stacking employed in the heat exchanger 409 allows the liquid coolant to be brought into proximity with the heated regions thereof, where the heat can be evenly distributed and discharged without increasing the footprint of the system 401. Stacked heat exchangers of the type shown in FIG. 7 have been fabricated which can handle average heat fluxes of more than 200 W/cm².

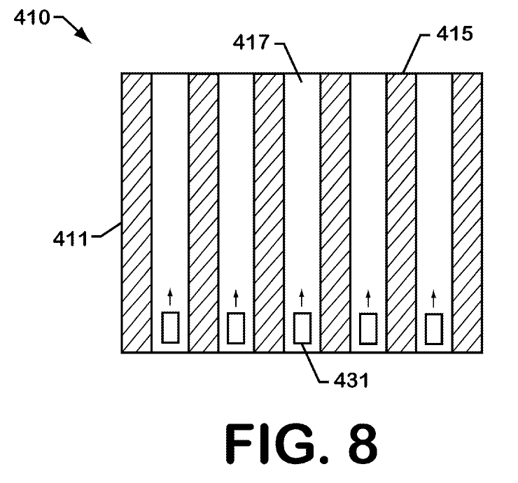

Various modifications are possible to the liquid loop cooling system depicted in FIG. 6. For example, a number of different heat exchangers can be used in place the heat exchanger depicted in FIG. 7. One such heat exchanger is shown in FIG. 8. In the heat exchanger 410 depicted therein, the synthetic jet actuators 431 are mounted within the microchannels 417, rather than being mounted on a wall of the chamber adjacent to the heat exchanger as shown in FIG. 6. In embodiments of this type, the synthetic jet actuators 431 preferably have a low profile so that their presence in the microchannel 417 will not significantly interfere with the egress of liquid coolant through the microchannels 417.

The systems and methodologies described herein, and the synthetic jet ejectors utilized in these systems and methodologies, can be implemented in various sizes and dimensions. Thus, for example, at the millimeter scale, synthetic jet ejectors can be integrated into liquid loops using commercially available piezoelectric transducers. At the micron scale, synthetic jet ejectors can be incorporated into the system utilizing conventional semiconductor fabrication techniques. At the nanometer scale, synthetic jet ejectors can be created using nano-scale lithography.

The synthetic jet ejectors utilized in the systems and methodologies described herein may operate on a continuous basis, or on a non-continuous basis. For example, the synthetic jet ejectors may be utilized on an on-demand basis, where they are activated when a temperature sensing probe disposed on a die or other heat-generating device reaches a prescribed temperature limit. The use of the synthetic jet ejectors on an on-demand basis may be advantageous in some applications from the standpoint of improving the reliability of the synthetic jet ejector, while maintaining the heat generating device within prescribed temperature limits.

The synthetic jet ejectors may also be configured to be driven at various frequencies, and the frequency at which a particular synthetic jet ejector is driven in a device of the type described herein may differ from the frequencies at which other synthetic jet ejectors in the device are driven. However, ultrasonic driving frequencies are preferred in many applications, since they reduce acoustic emissions in the audible region of the spectrum. Since actuator frequencies increase with decreasing size, ultrasonic operation becomes easier to implement as device sizes decrease. Hence, the systems and methodologies described herein are favored by Moore's law.

Various liquids may be utilized as the liquid coolant or medium in the devices and methodologies described herein. These include, without limitation, water and various organic liquids, such as, for example, polyethylene glycol, polypropylene glycol, and other polyols, partially fluorinated or perfluorinated ethers, and various dielectric materials. Liquid metals may also be advantageously used in the devices and methodologies described herein. Such materials are generally metal alloys with an amorphous atomic structure.

The systems and methodologies described herein may be used advantageously in a wide variety of applications where thermal management or boiling enhancement is desired. Such applications include, but are not limited to, single phase cooling enhancement applications (such as pool boiling applications), multiphase forced flow boiling applications, heat pipe applications, and thermosyphon applications.

One skilled in the art will also appreciate that the systems and methodologies described herein may be readily adapted for use in refrigeration applications. In such applications, the synthetic jet actuators described herein may be used, for example, to augment the flow of a refrigerant through the coils or surfaces of a heat exchanger. The use of synthetic jet actuators in these applications is especially suitable for use in miniaturized refrigeration systems, due to their ability to compensate for the pressure drop of refrigerant as it flows through the channels of a heat exchanger.

The above description of the present invention is illustrative, and is not intended to be limiting. It will thus be appreciated that various additions, substitutions and modifications may be made to the above described embodiments without departing from the scope of the present invention. Accordingly, the scope of the present invention should be construed in reference to the appended claims.

What is claimed is:

1. A thermal management system, comprising:
a liquid medium;
a heat generating device disposed in said medium;
a heat exchanger in thermal contact with said heat generating element, said heat transfer element comprising a thermally conductive material and having a channel defined on a surface thereof; and
a synthetic jet ejector adapted to direct a jet of the liquid medium along said channel.

2. The thermal management system of claim 1, wherein said heat exchanger has a plurality of channels defined in a surface thereof.

3. The thermal management system of claim 2, further comprising a plurality of synthetic jet ejectors, each being adapted to direct a jet of the liquid medium along one of said plurality of channels.

4. The thermal management system of claim 1, wherein said synthetic jet ejector is disposed adjacent to an opening of said channel.

5. The thermal management system of claim 1, wherein said synthetic jet ejector is disposed within said channel.

6. The thermal management system of claim 1, further comprising a pump adapted to create a flow of the liquid medium across the surface of said heat exchanger.

7. The thermal management system of claim 6, wherein said pump is a closed loop pump.

8. The thermal management system of claim 6, wherein said actuator is positioned such that it does not disrupt the flow of the liquid medium across the heat exchanger.

9. The thermal management system of claim 1, wherein said heat exchanger comprises a plurality of ridges which define a plurality of channels.

10. The thermal management system of claim 1, wherein the heat generating device is a die.

11. The thermal management system of claim 10, wherein said synthetic jet ejector comprises a diaphragm equipped with an actuator.

12. The thermal management system of claim 11, wherein said actuator is a piezoelectric actuator.

13. The thermal management system of claim 1, wherein said heat exchanger comprises a plurality of levels, and wherein each level has a plurality of channels defined therein.

14. The thermal management system of claim 13, wherein each of a plurality of channels within each of said plurality of levels has a synthetic jet ejector disposed therein.

15. The thermal management system of claim 13, wherein said heat exchanger is in fluidic communication with a heat sink.

16. The thermal management system of claim 15, wherein said heat sink is adapted to transfer heat from the liquid medium to the ambient atmosphere.

17. The thermal management system of claim 16, further comprising a pump which is adapted to maintain a flow of the liquid medium between said heat exchanger and said heat sink.

18. A method for cooling a heat generating device, comprising:
providing a heat generating device which is to be cooled, the heat generating device being in thermal contact with a heat exchanger which is immersed in a liquid medium and which has a channel defined in a surface thereof;
providing a synthetic jet ejector which is positioned to direct a jet of the liquid into said channel; and
activating the synthetic jet ejector.

19. The method of claim 18, wherein the synthetic jet ejector is activated when the device reaches a predetermined temperature threshold.

20. The method of claim 18, wherein the synthetic jet ejector is activated when the liquid medium reaches a predetermined temperature threshold.
